(19) United States
(12) Patent Application Publication
(10) Pub. No.: US 2009/0051050 A1
(43) Pub. Date: Feb. 26, 2009

(54) CORNER I/O PAD DENSITY

(75) Inventors: Gregory W. Bakker, San Jose, CA (US); Jonathan W. Greene, Palo Alto, CA (US)

Correspondence Address: LEWIS AND ROCA LLP, 1663 Hwy 395, Suite 201, Minden, NV, 89423, US

(73) Assignee: ACTEL CORPORATION

(21) Appl. No.: 11/844,881

(22) Filed: Aug. 24, 2007

(51) Int. Cl. H01L 23/49

(52) U.S. Cl. 257/784; 257/E23.024

(57) ABSTRACT

An integrated circuit die has a plurality of I/O cells disposed about its periphery, each I/O cell having an I/O bonding pad. A first group of I/O cells is disposed at the periphery of the die at locations away from corners of the die, each of the first group of I/O cells having an I/O pad disposed thereon and spaced at a first distance from the periphery of the die. A second group of I/O cells is disposed at the periphery of the die at locations away from corners of the die, each of the second group of I/O cells having an I/O pad disposed thereon and spaced at a distance from the periphery of the die more than the first distance, the distance increasing as a function of the proximity of each I/O cell to a corner of the die.

### BACKGROUND OF THE INVENTION

1. Field of the Invention

The present invention relates to integrated circuit layout technology. More particularly, the present invention relates to physical layouts for input/output (“I/O”) pads on integrated circuits.

2. The Prior Art

Conventionally, I/O bonding pads are all aligned in one (inline) or two (staggered) rows in the same way all along each side of an integrated circuit die. FIG. 1 shows a conventional placement of I/O pads 10 and driver cells 12 near a corner 18 of an integrated circuit die. Each I/O pad has a bonding wire 14 bonded to it as is known in the art. As may be seen from an examination of FIG. 1, some space is wasted due to the height of the I/O cells 12 exceeding the size of the open space (shown at dashed rectangle 16) required at the corner 18 of the die 20. Additional space is wasted because some number of outermost I/O pads (four shown in FIG. 1) along the end of each side need to be spaced at a wider pitch as indicated by reference numerals 22. This is due to the fact that the bonding wires 14 near the corners are angled at approximately 45 degrees as shown in FIG. 1 and yet an adequate spacing must be maintained between the wires.

As the number of required I/O connections for integrated circuits increases, the die size of integrated circuits is also shrinking, decreasing the available perimeter size in which to located the I/O cells and pads. Fitting a maximum number of I/O cells and pads around an integrated circuit die with limited perimeter space becomes increasingly challenging.

### BRIEF DESCRIPTION OF THE INVENTION

According to a first aspect of the present invention, I/O pads associated with I/O cells located near the corners of the die are located further from the periphery of the die and further from the edge of the integrated circuit die to allow for maintaining adequate wire spacing without needing to provide extra spacing between adjacent I/O pads at these locations.

According to another aspect of the present invention, bonding wires for alternate I/O pads near the corners are disposed at different heights. This increases the spacing between bonding wires associated with adjacent I/O pads, allowing the pads to be located closer together.

According to another aspect of the present invention, I/O cells that require smaller drivers may be disposed in otherwise wasted areas in the corners of the integrated circuit die. These aspects of the present invention may be used individually or in combination with one another.

### BRIEF DESCRIPTION OF THE DRAWING FIGURES

FIG. 1 is a diagram showing a top view of the physical layout of a typical prior-art I/O pad arrangement.

FIG. 2 is a diagram showing a top view of the physical layout of an I/O pad arrangement according to a first aspect of the present invention.

FIGS. 3A and 3B are, respectively, diagrams showing top and cross-sectional views of the physical layout of an I/O pad arrangement according to a second aspect of the present invention.

FIG. 4A is a diagram showing a top view of the physical layout of an I/O pad arrangement according to a third aspect of the present invention.

FIG. 4B is a diagram showing a top view of the physical layout of an I/O pad arrangement according to a variation of the third aspect of the present invention.

FIG. 5 is a diagram showing a top view of the physical layout of an I/O pad arrangement according to a variation of the present invention.

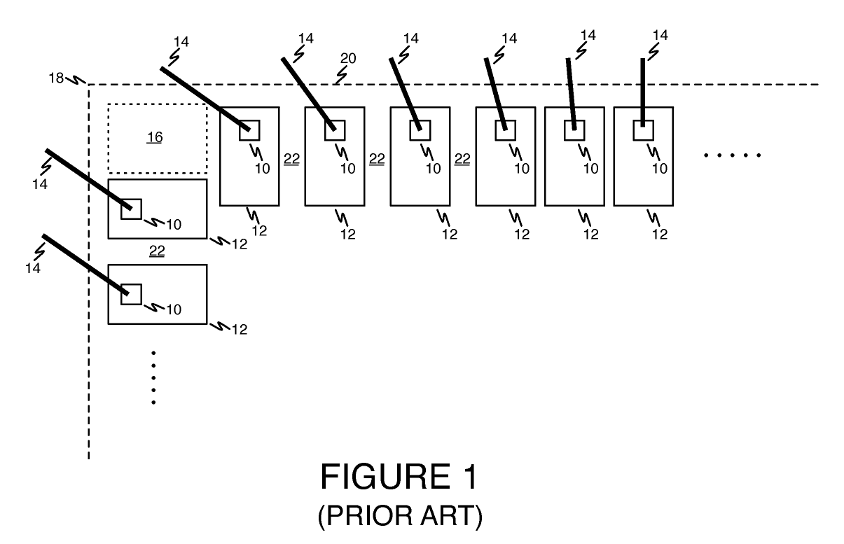

### DETAILED DESCRIPTION OF THE INVENTION

Persons of ordinary skill in the art will realize that the following description of the present invention is illustrative only and not in any way limiting. Other embodiments of the invention will readily suggest themselves to such skilled persons.

As will also be appreciated by persons of ordinary skill in the art, modern fabrication technology allows I/O pads to be placed over active circuitry. It is presently preferred to employ such technology in the present invention, which is shown in the drawing figures herein. However the invention does not require the use of pad-over-active technology and may be practiced without the use of such technology. In addition, it is to be understood that the various aspects of the present invention disclosed herein may be used individually or in combination with one another.

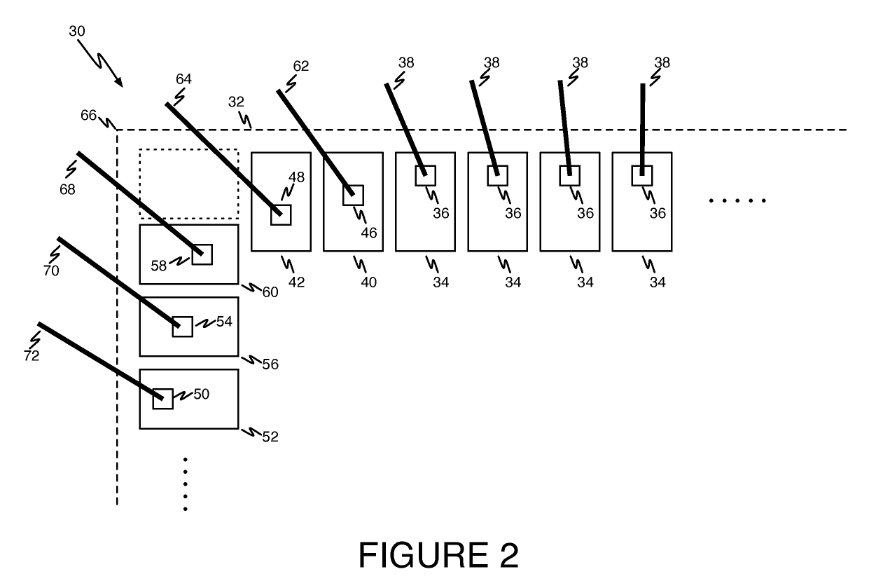

Referring now to FIG. 2, a diagram shows a top view of the physical layout of an I/O pad arrangement 30 for an integrated circuit die 32 according to a first aspect of the present invention. According to this aspect of the present invention, I/O cells 34 disposed away from the corners of the die have I/O pads 36 located at a first position as shown in FIG. 2. Bonding wires 38 are bonded to I/O pads 36 and extend to a lead frame (not shown) to which they are also bonded as is known in the art.

I/O cells 40 and 42 located at the top edge of die 32 near a corner thereof, have I/O pads that are located further from the edge of the integrated circuit die to allow for maintaining adequate wire spacing without needing to provide extra spacing between adjacent I/O pads at these locations where the wires may not be parallel to one another and are not perpendicular to the die edge. As the I/O cell gets closer to the corner 66 of die 32, its I/O pad is moved further from the edge of the die. As shown in FIG. 2, I/O pad 46 in I/O cell 40 is further from the edge of die 32 than are I/O pads 36 to its right. I/O pad 48, in I/O cell 42 nearest the corner 44 is further from the edge of die 32 than is I/O pad 46 to its immediate right.

Similarly, I/O pad 50 is located in the same relative place in I/O cell 52 on the left edge of die 32 as are I/O pads 36 in I/O cells 34. I/O pad 54 in I/O cell 56 is located further from the edge of the die 32 than is I/O pad 50 below it. I/O pad 58, in I/O cell 60 nearest the corner 44 is further from the edge of die 32 than is I/O pad 54 to its immediate right. While FIG. 2 shows two pads 46 and 48 located further from the edge of the die, persons of ordinary skill in the art will appreciate that one or more pads may be located further in from the edge of the die according to the present invention.

This arrangement according to this aspect of the present invention provides more spacing between bonding wires 62, 64, 66, 68, and 70 than would be the case using prior-art layout schemes. Furthermore, unlike the prior art arrangements, the arrangement according to this aspect of the present invention permits uniform spacing between all of I/O cells 34, 40, 42, 52, 56, and 60 while still providing additional spacing between adjacent bonding wires.

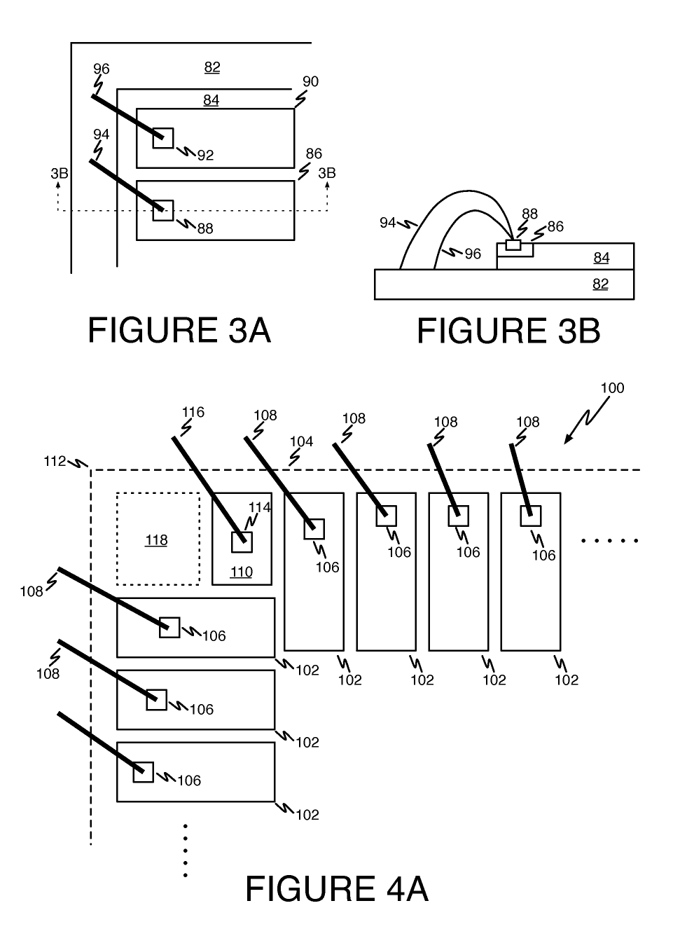

Referring now to FIGS. 3A and 3B, respectively, diagrams show top and side views of the physical layout of an I/O pad arrangement according to a second aspect of the present invention. The cross section of FIG. 3B is taken through the dashed line 3B-3B. According to this aspect of the present invention, bonding wires for alternate I/O pads near the corners are routed in upper and lower bonding-wire spaces. This increases the spacing between bonding wires associated with adjacent I/O pads, allowing the I/O pads to be located closer together.

Thus, as shown in FIGS. 3A and 3B, a package substrate 82 supports an integrated circuit die 84. A first I/O cell 86 is shown in the plane of the drawing figure. A bonding pad 88 is disposed in the I/O cell 86. A second I/O cell 90 has a bonding pad 92. A first bonding wire 94 is bonded to the bonding pad 88 and a second bonding wire 96 is bonded to the bonding pad 92. The first and second bonding wires extend to a lead frame (not shown) to which they are also bonded as is known in the art. As is most easily seen in FIG. 3B, bonding wires 94 and 96 describe arcs at different heights to avoid contact with one another. This scheme may be employed only near the corners of the chip where the bonding wires do not cross the die boundary at angles close to 90° and it is necessary to maintain a tight pitch between I/O cells. Conventionally, bonding wires disposed at two different heights are used only for staggered pad layouts, not for in-line pad layouts, and only uniformly along the entirety of each side of the chip.

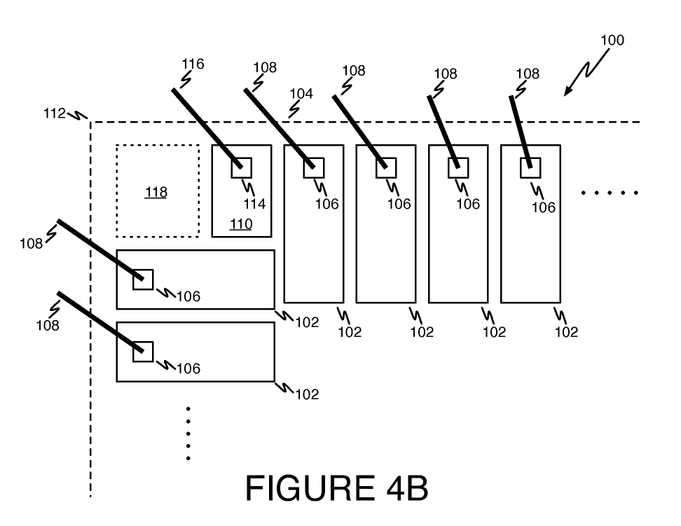

Referring now to FIG. 4A, a diagram shows a top view of the physical layout of an I/O pad arrangement according to a third aspect of the present invention. According to this aspect of the present invention, I/O cells that require smaller drivers may be disposed in otherwise unused areas in the corners of the integrated circuit die. For example, in FPGA integrated circuits, most I/Os require highly flexible I/O drivers, which are of necessity large. However, a few of the I/Os may need only much smaller drivers, e.g. those for JTAG test pins or special power supplies. These types of I/O are good candidates for laying out at the die corners.

Thus, in layout 100 a plurality of I/O cells 102 are disposed along the top edge of the periphery of an integrated circuit die 104. Similarly, additional I/O cells 102 are disposed along the left edge of the periphery of integrated circuit die 104. Each I/O cell includes an I/O pad 106 bonded to a bonding wire 108 which extends to a lead frame (not shown) to which they are also bonded. In one embodiment, for example where the integrated circuit is a programmable logic device, all of I/O cells 102 are of a general-purpose type, which means that they need to be designed to be versatile to be able to handle more than one function and are sized accordingly.

Another type of I/O cell 110 is also included in the layout 100. Unlike I/O cells 102, I/O cell 110 does not need to have as large a driver and may be sized smaller so as to fit in an area at the corner 112 of the die 104, as shown in FIG. 4A. I/O cell 110 has an I/O pad 114 to which a bonding wire 116 is attached. An unused area represented by the area within dashed lines 118 remains at the corner 112 of the die 104 as shown in FIG. 4A. However, this area 118 is smaller than the area that would otherwise exist. In some embodiments, the pads may be located at different distances from the edges of the die as shown in the figure.

As previously noted herein, persons of ordinary skill in the art will appreciate that the different I/O layout techniques disclosed herein may be used independently or in combination with one another. This is shown in FIG. 4A wherein, as in the embodiment of FIG. 2, the pads associated with I/O cells located near the corners of the die are located further from the edge of the die than are the pads associated with I/O cells further from the corners of the die.

FIG. 4B is a diagram showing a top view of the physical layout of an I/O pad arrangement according to a variation of the third aspect of the present invention. In most respects it is the same as the embodiment of FIG. 4A, but the pads associated with all of the I/O cells are placed at the same distance from the edges of the die.

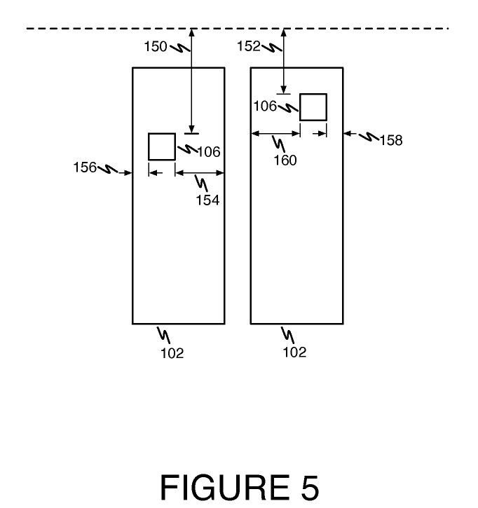

FIG. 5 is a diagram showing a top view of two I/O cells illustrating an I/O pad arrangement according to a variation of the present invention. As shown in FIG. 5, the total spacing between bond pads 106 (and thus the angles of the associated bonding wires, may be varied not only by varying the distance between the bond pad and the edge of the integrated circuit die (e.g., distance 150 is greater than distance 152), but also by varying the distance of the bonding pad from the edge of the I/O cell (e.g., distance 154 is greater than distance 156 and distance 158 is smaller than distance 160). In this way, the distances between I/O bonding pads may be optimized in more than one direction.

While embodiments and applications of this invention have been shown and described, it would be apparent to those skilled in the art that many more modifications than mentioned above are possible without departing from the inventive concepts herein. The invention, therefore, is not to be restricted except in the spirit of the appended claims.

What is claimed is:

1. In an integrated circuit die having a plurality of I/O cells disposed about a periphery of the die, a layout for the I/O cells comprising:
a first group of I/O cells disposed at the periphery of the die at locations away from corners of the die, each of the first group of I/O cells having an I/O bonding pad disposed thereon:
the I/O bonding pad spaced at a first distance from the periphery of the die, and
the I/O bonding pad bonded to a wire having an arc height;
a second group of I/O cells disposed at the periphery of the die closer to a corner of the die than I/O cells in the first group, the second group of I/O cells including at least one I/O cell, each of the second group of I/O cells having an I/O bonding pad disposed thereon:
each I/O bonding pad spaced at a distance from the periphery of the die greater than the first distance,
the distance of each I/O bonding pad of the second group of I/O cells from the periphery of the die increasing as a function of the proximity of each of the second group of I/O cells to a corner of the die, and
each of the I/O bonding pads of the second group of I/O cells bonded to a wire having an arc height; and
at least one I/O cell having an area smaller than an area of at least one of the I/O cells in the second group of I/O cells and disposed at the periphery of the die closer to at least one corner of the die than any of the second group of I/O cells and having an I/O bonding pad bonded to a wire having an arc height, wherein:
the bonding wires for a selected number of alternate I/O pads near the corners have different arc heights.

2. In an integrated circuit die having a plurality of I/O cells disposed about a periphery of the die, a layout for the I/O cells comprising:
a first group of I/O cells disposed at the periphery of the die at locations away from corners of the die, each of the first group of I/O cells having an I/O bonding pad disposed thereon, the I/O bonding pad spaced at a first distance from the periphery of the die; and
a second group of I/O cells disposed at the periphery of the die closer to corners of the die than I/O cells in the first group, the second group of I/O cells including at least one I/O cell, each of the second group of I/O cells having an I/O bonding pad disposed thereon, each I/O bonding pad spaced at a distance from the periphery of the die greater than the first distance, the distance of each I/O bonding pad of the second group of I/O cells increasing as a function of the proximity of each of the second group of I/O cells to a corner of the die.

3. The layout of claim 2, wherein:
the first and second groups of I/O cells each have a first area; and
the layout further comprising at least one I/O cell having a second area, the I/O cell disposed at the periphery of the die closer to at least one corner of the die than any of the second group of I/O cells, wherein:
the second area is smaller than the first area.

4. The layout of claim 2 wherein:
the bonding pads of the first and second groups of I/O cells each have a bonding wire bonded thereto; and
bonding wires for a selected number of alternate I/O pads near the corners have different arc heights.

5. In an integrated circuit die having a plurality of I/O cells disposed about a periphery of the die, a layout for the I/O cells comprising:
a first group of I/O cells disposed at the periphery of the die at locations away from corners of the die, each of the first group of I/O cells having a first area and having an I/O bonding pad disposed thereon; and
a second group of I/O cells disposed at the periphery of the die proximate to at least one corner of the die, each of the second group of I/O cells having a second area smaller than the first area and having an I/O bonding pad disposed thereon.

6. The layout of claim 5 wherein:
the I/O bonding pads of ones of the first group of I/O cells disposed at the periphery of the die at locations away from corners of the die are spaced at a first distance from the periphery of the die; and
the I/O bonding pads of ones of the first group of I/O cells disposed at the periphery of the die at locations away from corners of the die are spaced at a distance from the periphery of the die greater than the first distance, the distance increasing as a function of the proximity of each I/O cell to a corner of the die.

7. The layout of claim 5, wherein:
the bonding pads of the first and second groups of I/O cells each have a bonding wire bonded thereto; and
bonding wires for a selected number of alternate I/O pads near the corners have different arc heights.

8. In an integrated circuit die having a plurality of I/O cells disposed about a periphery of the die, a layout for the I/O cells comprising:
a first group of I/O cells disposed at the periphery of the die at locations away from corners of the die, each of the first group of I/O cells having an I/O bonding pad disposed thereon;
a second group of I/O cells disposed at the periphery of the die at locations closer to corners of the die than I/O cells in the first group, each of the second group of I/O cells having an I/O bonding pad disposed thereon; and
bonding wires bonded to and extending outward from each bonding pad, wherein:
the bonding wires for the first group of I/O cells all have substantially the same arc heights; and
the bonding wires for the second group of I/O cells have first and second positions for alternate ones of the second group of I/O cells, the bonding wires at the first position having different arc heights than the bonding wires in the second position.

9. The layout of claim 8, wherein the first group of I/O cells has a first area and the second group of I/O cells has a second area;
the layout further comprising at least one additional I/O cell having a third area, the additional I/O cell disposed at the periphery of the die closer to at least one corner of the die than any of the second group of I/O cells, wherein:
the third area is less than the first and second areas.

10. The layout of claim 8 wherein:
the I/O bonding pads of ones of the first group of I/O cells are spaced at a first distance from the periphery of the die; and
the I/O bonding pads of the second group of I/O cells are spaced at a distance from the periphery of the die greater than the first distance, the distance increasing as a function of the proximity of each of the second group of I/O cells to a corner of the die.

11. In an integrated circuit die having a plurality of I/O cells disposed about a periphery of the die, a layout for the I/O cells comprising:
I/O cells disposed at the periphery of the die, each of the I/O cells having:
a first edge located closest to the periphery of the die and substantially parallel thereto;
a second edge substantially parallel to the first edge;
a third edge;
a fourth edge; and
a bonding pad; wherein:
the bonding pad of at least one of the I/O cells is located a distance from the third edge of the I/O cell greater than a distance from the fourth edge of the I/O cell.

12. The layout of claim 11, wherein:
the I/O cells comprise a first group of I/O cells, each having a first area; and
the layout further comprises at least one additional I/O cell having a second area, the additional I/O cell disposed at the periphery of the die closer to at least one corner of the die than any of the I/O cells of the first group of I/O cells, wherein:
the second area is smaller than the first area.

13. The layout of claim 11, wherein:
the bonding pads of the I/O cells each have a bonding wire bonded thereto; and
bonding wires for a selected number of alternate I/O pads have different arc heights.
